(19) United States
(12) Patent Application Publication
(10) Pub. No.: US 2026/0156746 A1
(43) Pub. Date: Jun. 4, 2026

(54) CIRCUIT SUBSTRATE AND MANUFACTURING METHODTOF

(71) Applicant: INDUSTRIAL TECHNOLOGY RESEARCH INSTITUTE, Hsinchu (TW)

(72) Inventors: WEI-HONG HONG, Hsinchu City (TW); YU-WEI HUANG, Chiayi City (TW)

(21) Appl. No.: 18/966,190

(22) Filed: Dec. 3, 2024

(51) Int. Cl. H05K 1/11; H05K 1/02; H05K 1/03; H05K 3/06

(52) U.S. Cl. CPC H05K 1/115; H05K 1/0213; H05K 1/0306; H05K 3/06

(57) ABSTRACT

A circuit substrate includes a dielectric layer, a first conductor layer, a first ground element and a plurality of signal traces. The first conductor layer is disposed on one side of the dielectric layer. The first ground element protrudes from the first conductor layer and disposed inside the dielectric layer. The signal traces are disposed inside the dielectric layer and located on one side of the first ground element. The projection of each signal trace on the first conductor layer is close to the projection of the first ground element on the first conductor layer, but the projection of each signal trace on the first conductor layer does not contact the projection of the first ground element on the first conductor layer.

### TECHNICAL FIELD

The disclosure relates to a circuit substrate, in particular to a circuit substrate having a protruding ground barrier. The disclosure further relates to the manufacturing method of the circuit substrate.

### BACKGROUND

With advancements in technology, the demand for integrated circuit substrates has significantly increased. Therefore, it has become an important issue to improve the performance of integrated circuit substrates.

Most of currently available integrated circuit substrates reduce crosstalk by decreasing coupling (e.g., by decreasing the coupling coefficient or coupling length). For example, there are two main approaches to reduce coupling: one is to reduce the coupling coefficient, and the other is to reduce the coupling length.

However, for the D2D (Die-to-Die) connection structures of the modern 2.XD (e.g., 2.1D, 2.3D, 2.5D) or 3D packaging architectures, the coupling length has already been reduced to near the technological bottleneck. Therefore, it is difficult to further lower crosstalk by reducing the coupling length.

Currently available integrated circuit substrates primarily reduce the coupling coefficient by two methods. One method is to significantly increase the pitch of signal traces to reduce the coupling coefficient. The other method is to introduce a ground trace between two signal traces.

### SUMMARY

One embodiment of the disclosure discloses a circuit substrate, the circuit substrate includes a dielectric layer, a first conductor layer, a first ground element and a plurality of signal traces. The first conductor layer is disposed on one side of the dielectric layer. The first ground element protrudes from the first conductor layer and disposed inside the dielectric layer. The signal traces are disposed inside the dielectric layer and located on one side of the first ground element. The projection of each signal trace on the first conductor layer is close to the projection of the first ground element on the first conductor layer, but the projection of each signal trace on the first conductor layer does not contact the projection of the first ground element on the first conductor layer.

Another embodiment of the disclosure discloses a circuit substrate, the circuit substrate includes a dielectric layer, a first conductor layer, a plurality of first ground elements and a plurality of signal traces. The first conductor layer is disposed on one side of the dielectric layer. The first ground elements protrude from the first conductor layer and are disposed inside the dielectric layer. The signal traces are disposed inside the dielectric layer and located on one side of the first ground element. The projection of each of the signal traces on the first conductor layer is adjacent to the projection of at least one of the first ground elements on the first conductor layer, but does not contact the projection of any one of the first ground elements on the first conductor layer.

Still another embodiment of the disclosure discloses a method for manufacturing a circuit substrate, the circuit substrate includes the following steps. an insulating substrate is provided. A first metal layer coating process by perform to form a first metal layer on the insulating substrate. A first lithography process by perform on the first metal layer to form a first grounding element and a first conductor layer. A dielectric layer formation process by perform to form a dielectric layer covering the first conductor layer and the first ground element. An opening process by perform to form an opening in the dielectric layer to expose the first ground element through the opening. A second metal layer coating process by perform to form a second metal layer on the dielectric layer. A grinding process by perform to remove portions of the second metal layer outside the opening in the dielectric layer. A third metal layer coating process by perform to form a third metal layer on the dielectric layer. and A second lithography process by perform on the third metal layer to form a plurality of signal traces.

As described above, the circuit substrate includes the first grounding element, which protrudes from the first conductor layer of the circuit substrate and is disposed inside the dielectric layer of the circuit substrate. The signal traces of the circuit substrate are disposed inside the dielectric layer and located on one side of the first ground element. The projection of each signal trace on the first conductor layer is adjacent to the projection of the first grounding element on the first conductor layer, but the projection of each signal trace on the first conductor layer does not contact the projection of the first grounding element on the first conductor layer. The first ground element protrudes from the first conductor layer to form a protruding ground barrier, which can effectively isolate electromagnetic fields and reduce crosstalk between signal traces. As a result, the circuit substrate effectively addresses the issue of crosstalk arising during high-speed signal transmission and high-frequency operation, so the circuit substrate can meet the requirements of various applications.

Additionally, each signal trace of the circuit substrate is extremely close to at least one first ground element but does not contact the first grounding element. Consequently, the first ground element not only serves as a protruding ground barrier to effectively isolate electromagnetic fields and reduce crosstalk between signal traces, but also avoids conductive anodic filament (CAF) and leakage currents. Thus, the reliability of the circuit substrate can be enhanced, such that the circuit substrate can conform to actual requirements.

Furthermore, the structural design of the circuit substrate provides a scalable structure that can be integrated with currently available manufacturing processes and applied to various heterogeneous packaging structures. Therefore, the circuit substrate can achieve significant area reduction while supporting high signal transmission density. As a result, the computational performance and processing time of the circuit substrate can be greatly improved, so the circuit substrate can satisfy the demands of high-performance computing (HPC) and artificial intelligence (AI) fields. Therefore, the circuit substrate aligns with the trends of future development.

### BRIEF DESCRIPTION OF THE DRAWINGS

FIG. 1 is a cross-section view of a circuit substrate in accordance with a first embodiment of the disclosure.

FIG. 2 is a first schematic view of the circuit substrate in accordance with the first embodiment of the disclosure.

FIG. 3 is a second schematic view of the circuit substrate in accordance with the first embodiment of the disclosure.

FIG. 4 is a cross-section view of a circuit substrate in accordance with a second embodiment of the disclosure.

FIG. 5 is a first schematic view of the circuit substrate in accordance with the second embodiment of the disclosure.

FIG. 6 is a second schematic view of the circuit substrate in accordance with the second embodiment of the disclosure.

FIG. 7 is a cross-section view of a circuit substrate in accordance with a third embodiment of the disclosure.

FIG. 8 is a cross-section view of a circuit substrate in accordance with a fourth embodiment of the disclosure.

FIG. 9 is a cross-section view of a circuit substrate in accordance with a fifth embodiment of the disclosure.

FIG. 10 is a cross-section view of a circuit substrate in accordance with a sixth embodiment of the disclosure.

FIG. 11 is a cross-section view of a circuit substrate in accordance with a seventh embodiment of the disclosure.

FIG. 12 is a cross-section view of a circuit substrate in accordance with an eighth embodiment of the disclosure.

FIG. 13 is a cross-section view of a circuit substrate in accordance with a ninth embodiment of the disclosure.

FIG. 14 is a first curve chart of an electromagnetic simulation of the circuit substrates of the embodiments of the disclosure.

FIG. 15 is a second curve chart of the electromagnetic simulation of the circuit substrates of the embodiments of the disclosure.

FIG. 16A to FIG. 16H are first to eighth schematic views of a method for manufacturing a circuit substrate in accordance with a tenth embodiment of the disclosure.

FIG. 17 is a flow chart of a method for manufacturing a circuit substrate in accordance with an eleventh embodiment of the disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing. It should be understood that, when it is described that an element is “coupled” or “connected” to another element, the element may be “directly coupled” or “directly connected” to the other element or “coupled” or “connected” to the other element through a third element. In contrast, it should be understood that, when it is described that an element is “directly coupled” or “directly connected” to another element, there are no intervening elements.

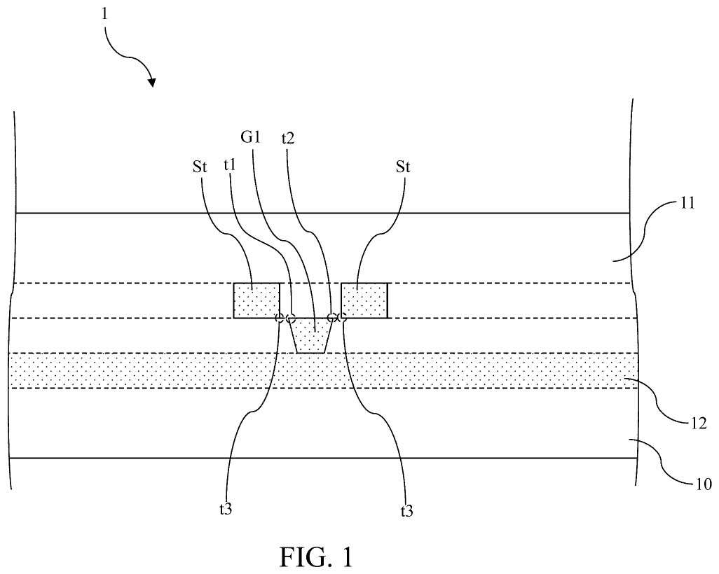

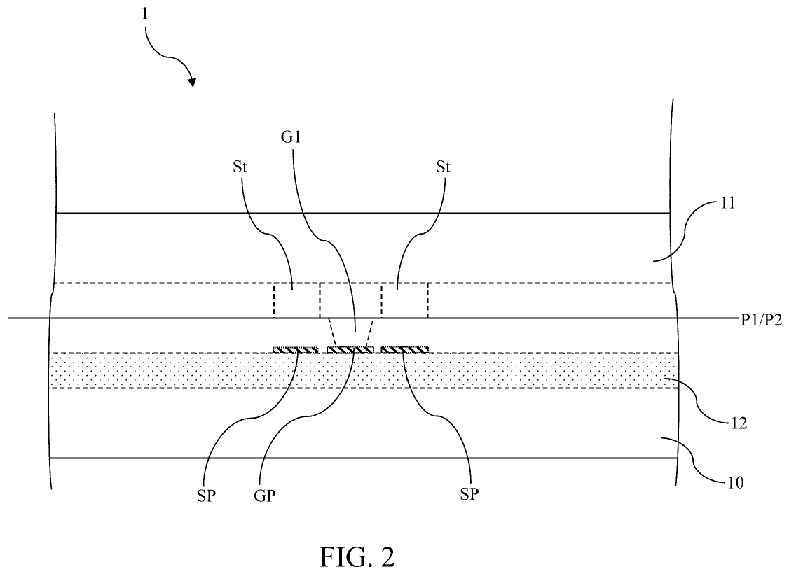

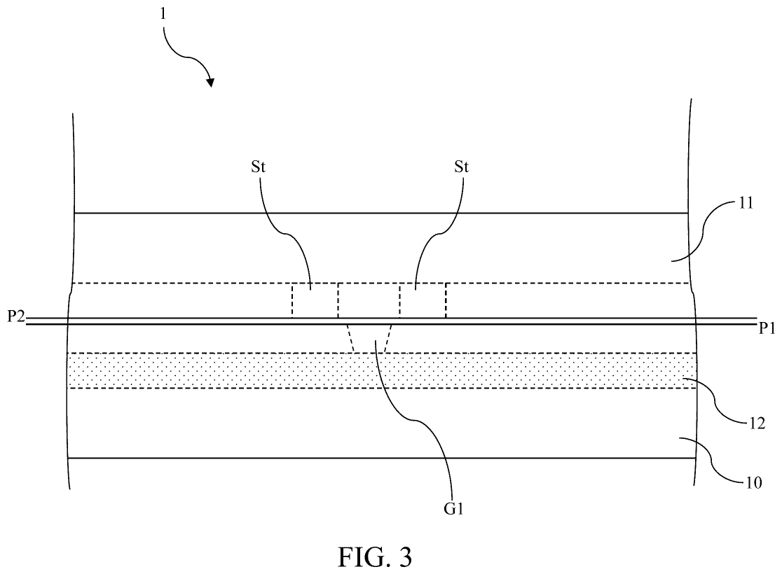

Please refer to FIG. 1, FIG. 2, and FIG. 3. FIG. 1 is a cross-section view of a circuit substrate in accordance with a first embodiment of the disclosure. FIG. 2 is a first schematic view of the circuit substrate in accordance with the first embodiment of the disclosure. FIG. 3 is a second schematic view of the circuit substrate in accordance with the first embodiment of the disclosure. As shown in FIG. 1, the circuit substrate 1 includes an insulating substrate 10, a dielectric layer 11, a first conductor layer 12, a first ground element G1, and two signal traces St. The circuit substrate 1 can be a multilayer substrate.

The first conductor layer 12 is disposed on the insulating substrate 10 and on one side of the dielectric layer 11. In this embodiment, the first conductor layer 12 is located on the lower side of the dielectric layer 11. The first conductor layer 12 may be made of copper or other suitable metal materials. The dielectric layer 11 can be made of dielectric materials, such as a PI film or other suitable dielectric materials. In this embodiment, the insulating substrate 10 is a glass substrate. In another embodiment, the insulating substrate 10 may also be a dielectric layer.

The first ground element G1 protrudes from the first conductor layer 12 and is disposed inside the dielectric layer 11. The first ground element G1 can be a via. In another embodiment, the first ground element G1 may also be a ground trace.

The signal traces St are disposed inside the dielectric layer 11 and located on the upper left and upper right sides of the first ground element G1. That is, the dielectric layer 11 includes a signal layer and a ground layer, where the signal traces St are disposed in the signal layer, and the ground element G1 is disposed in the ground layer. The signal layer is located above the ground layer, while the ground layer is located above the first conductor layer 12. The signal traces St may be made of a metal, such as copper or other suitable metals.

As shown in FIG. 1, in this embodiment, the first ground element G1 is located below the two signal traces St and between the two signal traces St in order to provide an electromagnetic isolation effect. The first ground element G1 is adjacent to the two signal traces St but does not touch the two signal traces St. The top surface of the first ground element G1 has a left-end corner t1 and a right-end corner t2, while the bottom surface of each signal trace St has an inner-end corners t3 near the first ground element G1. The left-end corner t1 and right-end corner t2 of the top surface of the first ground element G1 are very close to but do not touch the inner-end corner t3 of the bottom surface of any one of the signal traces St. The same applies to subsequent embodiments. The first ground element G1 can be inverted trapezoidal in shape, and the signal traces St can be rectangular. In other embodiments, the first ground element G1 may be trapezoidal, rectangular, pentagonal, other polygons, or other suitable shapes. The signal traces St may also be trapezoidal, inverted trapezoidal, pentagonal, other polygons, or other suitable shapes. This embodiment is not limited to these examples, and the same applies to subsequent embodiments.

As shown in FIG. 2, the projections SP of the signal traces St on the first conductor layer 12 are adjacent to the projections GP of the first ground element G1 on the first conductor layer 12. However, the projections SP of the signal traces St on the first conductor layer 12 do not contact the projections GP of the first ground element G1 on the first conductor layer 12. The projections SP of the signal traces St can be very close to the projections GP of the first ground element G1 but do not contact the projections GP of the first ground element G1. The signal traces St also do not contact the first ground element G1. The distance between the projections SP of each signal trace St and the projections GP of the first ground element G1 on the first conductor layer 12 (the shortest distance between the signal trace St and the first ground element G1) can range from 1 μm to 10 μm, such as 3 μm or 5 μm, which can be adjusted as needed.

Moreover, the plane P1 passing through the top surface of the first ground element G1 may coincide with the plane P2 passing through the bottom surfaces of the signal traces St.

As described above, the first ground element G1 protrudes from the first conductor layer 12, and the two signal traces St are disposed above and on both sides of the first ground element G1. The signal traces Sr are very close to the first ground element G1 but do not contact the first ground element G1. The first ground element G1 protruding from the first conductor layer 12 forms an effective protruding ground barrier that isolates the electromagnetic field. Thus, the first ground element G1 can significantly reduce crosstalk between the signal traces St.

Further, since the signal traces St on the circuit substrate 1 are extremely close to but do not contact the first ground element G1, the first ground element G1 not only forms a protruding ground barrier to effectively isolate the electromagnetic field and reduce crosstalk between the signal traces St but also prevents conductive anodic filament (CAF) and leakage currents.

As shown in FIG. 3, there may be a gap between the plane P1 passing through the top surface of the first ground element G1 and the plane P2 passing through the bottom surfaces of the signal traces St.

The embodiment just exemplifies the disclosure and is not intended to limit the scope of the disclosure. Any equivalent modification and variation according to the spirit of the disclosure is to be also included within the scope of the following claims and their equivalents.

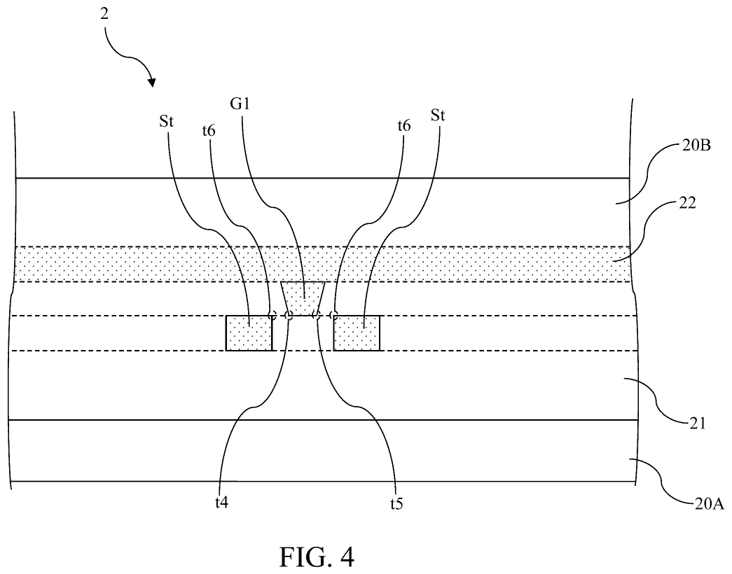

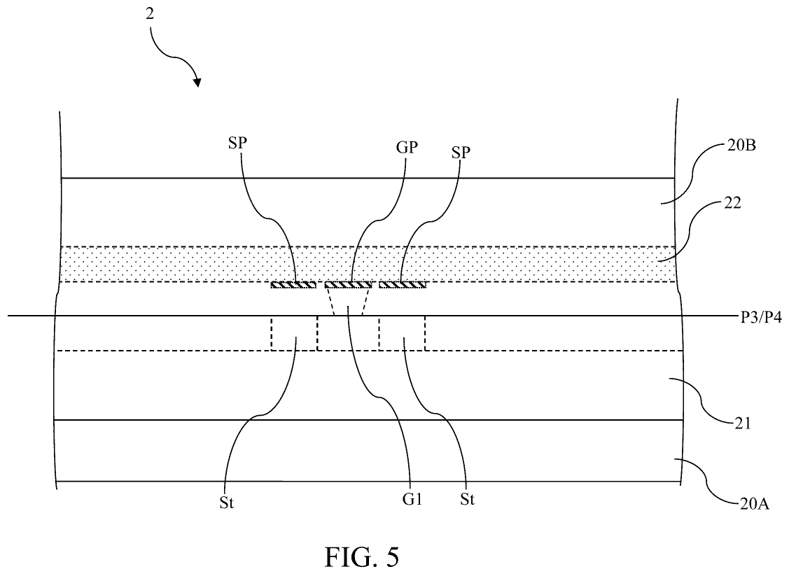

Please refer to FIG. 4, FIG. 5, and FIG. 6. FIG. 4 is a cross-section view of a circuit substrate in accordance with a second embodiment of the disclosure. FIG. 5 is a first schematic view of the circuit substrate in accordance with the second embodiment of the disclosure. FIG. 6 is a second schematic view of the circuit substrate in accordance with the second embodiment of the disclosure. As shown in FIG. 4, the circuit substrate 2 includes a first insulating substrate 20A, a second insulating substrate 20B, a dielectric layer 21, a first conductor layer 22, a first ground element G1, and two signal traces St. That is, the dielectric layer 21 includes a signal layer and a ground layer. The signal traces St are disposed in the signal layer, and the ground element G1 is disposed in the ground layer. The ground layer is disposed above the signal layer, while the ground layer is disposed below the first conductor layer 22. The circuit substrate 2 can be a multilayer substrate.

The first conductor layer 22 is disposed on one side of the dielectric layer 21. In this embodiment, the first conductor layer 22 is disposed on the upper side of the dielectric layer 21. The dielectric layer 21 is disposed on the first insulating substrate 20A. The second insulating substrate 20B is disposed on the first conductor layer 22. In this embodiment, the first insulating substrate 20A and the second insulating substrate 20B are glass substrates. In another embodiment, the first insulating substrate 20A and the second insulating substrate 20B may also be dielectric layers.

The first ground element G1 protrudes from the first conductor layer 22 and is disposed inside the dielectric layer 21.

The signal traces St are disposed inside the dielectric layer 21 and located on one side of the first ground element G1. The signal traces St may be made of a metal such as copper or other suitable metals. The first ground element G1 is adjacent to the two signal traces St but does not touch these signal traces St. The bottom surface of the first ground element G1 has a left-end corner t4 and a right-end corner t5, while the top surface of each signal trace St has an inner-end corners t6 near the first ground element G1. The left-end corner t4 and right-end corner t5 of the bottom surface of the first ground element G1 are close to but do not touch the inner-end corner t6 of the top surface of any one of the signal traces St. The same applies to subsequent embodiments.

As described above, in this embodiment, the first ground element G1 is disposed above the two signal traces St and located between these signal traces St so as to provide an electromagnetic isolation effect.

As shown in FIG. 5, the projections SP of the signal traces St on the first conductor layer 22 are adjacent to the projection GP of the first ground element G1 on the first conductor layer 22. However, the projections SP of the signal traces St on the first conductor layer 22 do not contact the projection GP of the first ground element G1 on the first conductor layer 22. The projections SP of the signal traces St can be very close to the projections GP of the first ground element G1 but do not touch the projections GP of the first ground element G1. The signal traces St also do not contact the first ground element G1. Similarly, the distance between the projection SP of each signal trace St and the projection GP of the first ground element G1 on the first conductor layer 22 (the shortest distance between the signal trace St and the first ground element G1) can be adjusted as needed.

Additionally, the plane P3 passing through the bottom surface of the first ground element G1 may coincide with and the plane P4 passing through the top surfaces of the signal traces St.

Similar to the previous embodiment, the first ground element G1 protrudes from the first conductor layer 22, and the two signal traces St are disposed below and on both sides of the first ground element G1. The first ground element G1 protruding from the first conductor layer 22 forms an effective protruding ground barrier that isolates the electromagnetic field. Thus, the first ground element G1 can significantly reduce crosstalk between the signal traces St.

Similarly, since the signal traces St on the circuit substrate 2 are extremely close to but do not contact the first ground element G1, the first ground element G1 not only forms a protruding ground barrier to effectively isolate the electromagnetic field and reduce crosstalk between the signal traces St but also prevents conductive anodic filament (CAF) and leakage currents.

As shown in FIG. 6, there may also be a gap between the plane P3 passing through the bottom surface of the first ground element G1 and the plane P4 passing through the top surfaces of the signal traces St.

The embodiment just exemplifies the disclosure and is not intended to limit the scope of the disclosure. Any equivalent modification and variation according to the spirit of the disclosure is to be also included within the scope of the following claims and their equivalents.

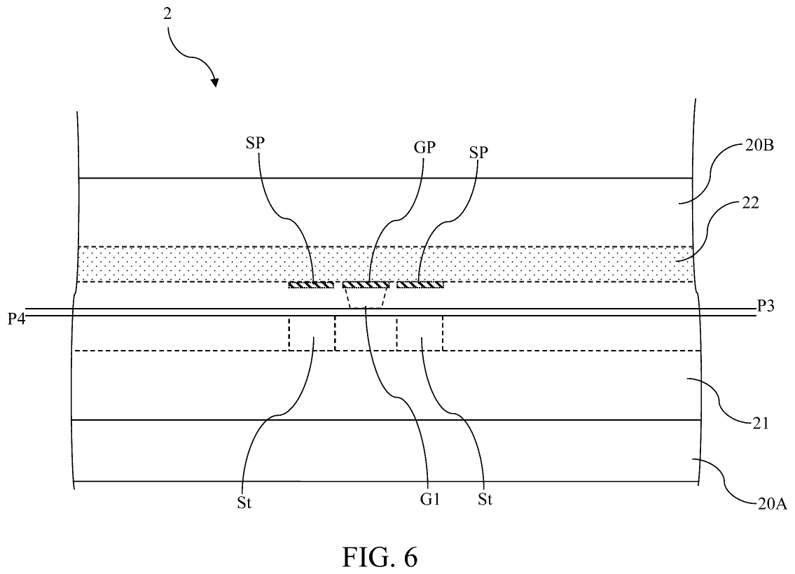

Please refer to FIG. 7, which is a cross-section view of a circuit substrate in accordance with a third embodiment of the disclosure. As shown in FIG. 7, the circuit substrate 3 includes a first insulating substrate 30A, a second insulating substrate 30B, a dielectric layer 31, a first conductor layer 32, a second conductor layer 33, a first ground element G1, a second ground element G2, and two signal traces St. The above structure is similar to the previous embodiments, so the detailed description of the above structure will not be repeated herein.

The first conductor layer 32 is disposed on the first insulating substrate 30A and located on one side of the dielectric layer 31. In this embodiment, the first conductor layer 32 is disposed on the lower side of the dielectric layer 31.

The first ground element G1 protrudes from the first conductor layer 32 and is disposed inside the dielectric layer 31.

The signal traces St are disposed inside the dielectric layer 31 and located on one side of the first ground element G1.

The second conductor layer 33 is disposed on the other side of the dielectric layer 31. In this embodiment, the second conductor layer 33 is disposed on the upper side of the dielectric layer 31. The second insulating substrate 30B is disposed on the second conductor layer 33. In this embodiment, both the first insulating substrate 30A and the second insulating substrate 30B are glass substrates. In another embodiment, the first and second insulating substrates may also be dielectric layers.

The second ground element G2 protrudes from the second conductor layer 33 and is disposed inside the dielectric layer 31. The second ground element G2 may be a via. In another embodiment, the second ground element G2 may also be a ground trace.

As previously stated, in this embodiment, the first ground element G1 is disposed below the two signal traces St, while the second ground element G2 is disposed above the two signal traces St. The first ground element G1 is disposed between the signal traces St, and the second ground element G2 is also disposed between the signal traces St with a view to providing an electromagnetic isolation effect.

The projections of the signal traces St on the first conductor layer 32 are adjacent to the projection of the first ground element G1 on the first conductor layer 32. However, the projections of the signal traces St on the first conductor layer 32 do not contact the projection of the first ground element G1 on the first conductor layer 32. Similarly, the projections of the signal traces St on the second conductor layer 33 are adjacent to the projection of the second ground element G2 on the first conductor layer 32 but do not contact the projection of the second ground element G2 on the first conductor layer 32. The signal traces St also do not contact the first ground element G1 or the second ground element G2. The distance between the projection of each the signal trace St and the first ground element G1 on the first conductor layer 32 can range from 1 μm to 10 μm, such as 3 μm or 5 μm, which can be adjusted as needed. Similarly, the distance between the projection of each the signal trace St and the second ground element G2 on the second conductor layer 33 can range from 1 μm to 10 μm, such as 3 μm or 5 μm, which can be adjusted as needed.

Additionally, the plane passing through the top surface of the first ground element G1 may coincide with the plane passing through the bottom surfaces of the signal traces St. There may also be a gap between the plane passing through the top surface of the first ground element G1 and the plane passing through the bottom surfaces of the signal traces St. Similarly, the plane passing through the bottom surface of the second ground element G2 may coincide with the plane passing through the top surfaces of the signal traces St. There may also be a gap between the plane passing through the bottom surface of the second ground element G2 and the plane passing through the top surfaces of the signal traces St.

As described above, the first ground element G1 protrudes from the first conductor layer 32, and the two signal traces St are disposed above and on both sides of the first ground element G1. The first ground element G1 protruding from the first conductor layer 32 forms an effective protruding ground barrier to isolate the electromagnetic field. The second ground element G2 protrudes from the second conductor layer 33, and the two signal traces St are disposed below and on both sides of the second ground element G2. The second ground element G2 protruding from the second conductor layer 33 forms an effective protruding ground barrier to isolate the electromagnetic field. The combination of the first ground element G1 and the second ground element G2 significantly reduces crosstalk between the signal traces St.

In addition, since the signal traces St are extremely close to but do not contact the first ground element G1 and the second ground element G2, these ground elements not only form effective protruding ground barriers to isolate the electromagnetic field and reduce crosstalk but also prevent conductive anodic filament (CAF) and leakage currents.

The embodiment just exemplifies the disclosure and is not intended to limit the scope of the disclosure. Any equivalent modification and variation according to the spirit of the disclosure is to be also included within the scope of the following claims and their equivalents.

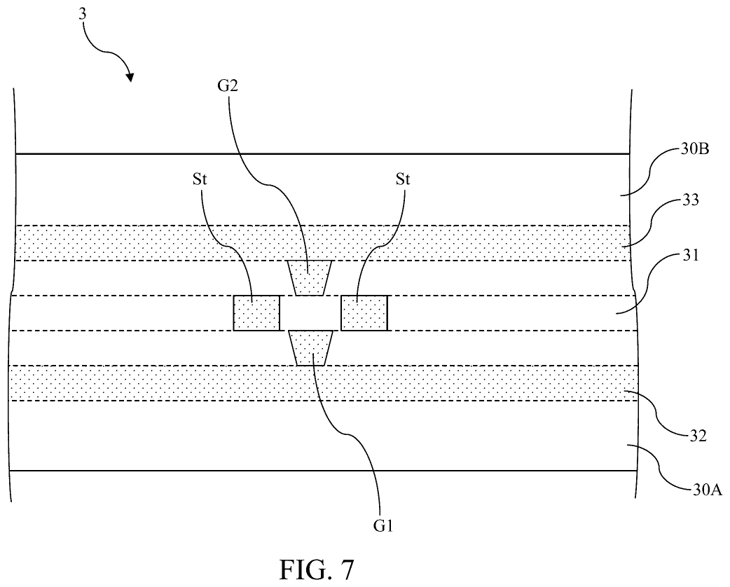

Please refer to FIG. 8, which is a cross-section view of a circuit substrate in accordance with a fourth embodiment of the disclosure. As shown in FIG. 8, the circuit substrate 4 includes an insulating substrate 40, a dielectric layer 41, a first conductor layer 42, two first ground elements G1, and two signal traces St. The above structure is similar to the previous embodiments, so the detailed description of the above structure will not be repeated herein.

The first conductor layer 42 is disposed on the insulating substrate 40 and located on one side of the dielectric layer 41. In this embodiment, the first conductor layer 42 is disposed on the lower side of the dielectric layer 41.

The first ground elements G1 protrude from the first conductor layer 42 and are disposed inside the dielectric layer 41.

The signal traces St are disposed inside the dielectric layer 41 and located on one side of the first ground elements G1.

As described above, in this embodiment, the two first ground elements G1 are disposed below the two signal traces St, and the signal traces St are disposed between the first ground elements G1 to provide an electromagnetic isolation effect.

The projections of the signal traces St on the first conductor layer 42 are adjacent to the projection of at least one of the first ground elements G1 on the first conductor layer 42. However, the projections of the signal traces St do not contact the projection of any one of the first ground elements G1. In this embodiment, the projections of the signal traces St are located between the projections of the first ground elements G1. The distance between the projection of each signal trace St and the first ground elements G1 (the shortest distance between the signal trace St and the first ground element G1) is already described in previous embodiments.

Additionally, the plane passing through the top surface of the first ground elements G1 may coincide with the plane passing through the bottom surfaces of the signal traces St. There may also be a gap between the plane passing through the top surface of the first ground elements G1 and the plane passing through the bottom surfaces of the signal traces St.

As set forth above, the first ground elements G1 protrude from the first conductor layer 42, and the two signal traces St are disposed above and between the first ground elements G1. This structure can significantly reduce crosstalk between the signal traces St. The number of first ground elements G1 and signal traces St can vary depending on actual requirements. The positions of the first ground elements G1 and signal traces St can also be adjusted based on actual requirements.

The embodiment just exemplifies the disclosure and is not intended to limit the scope of the disclosure. Any equivalent modification and variation according to the spirit of the disclosure is to be also included within the scope of the following claims and their equivalents.

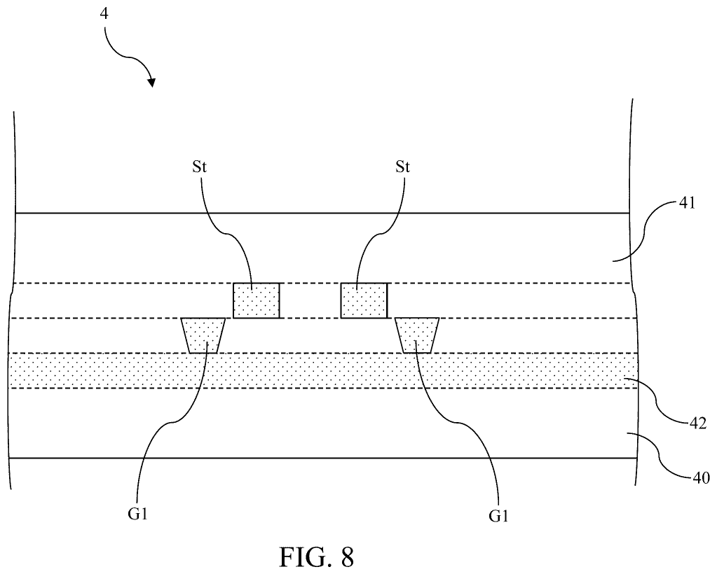

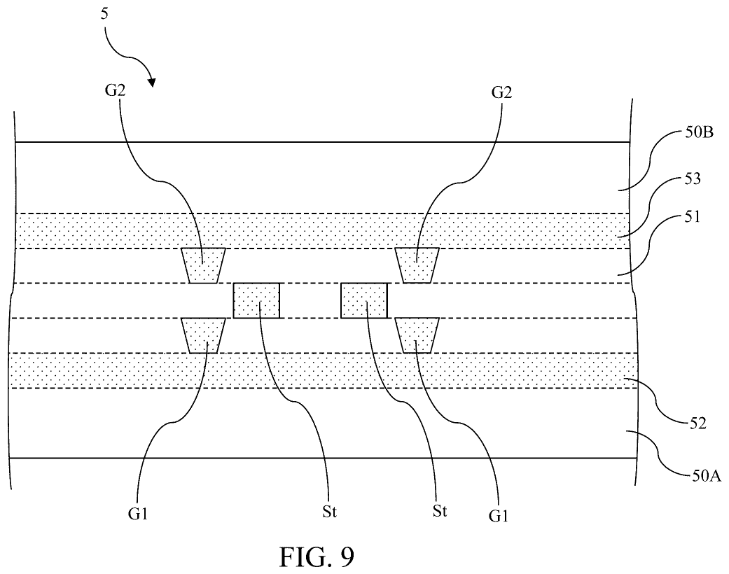

Please refer to FIG. 9, which is a cross-section view of a circuit substrate in accordance with a fifth embodiment of the disclosure. As shown in FIG. 9, the circuit substrate 5 includes a first insulating substrate 50A, a second insulating substrate 50B, a dielectric layer 51, a first conductor layer 52, a second conductor layer 53, two first ground elements G1, two signal traces St, and two second ground elements G2. The above structure is similar to the previous embodiments, so the detailed description of the above structure will not be repeated herein.

The first conductor layer 52 is disposed on the first insulating substrate 50A and located on one side of the dielectric layer 51. In this embodiment, the first conductor layer 52 is disposed on the lower side of the dielectric layer 51.

The first ground elements G1 protrude from the first conductor layer 52 and are disposed inside the dielectric layer 51.

The signal traces St are disposed inside the dielectric layer 51 and located on one side of the first ground elements G1.

The difference between this embodiment and the fourth embodiment is that this embodiment further includes two second ground elements G2 and a second conductor layer 53 disposed above the signal traces St. The second ground elements G2 are disposed above the signal traces St and located on both sides of the signal traces St, symmetrically with the first ground elements G1. The second conductor layer 53 is disposed on the upper side of the dielectric layer 51, and the second ground elements G2 protrude from the second conductor layer 53. The second insulating substrate 50B is disposed on the second conductor layer 53. In this embodiment, both the first insulating substrate 50A and the second insulating substrate 50B are glass substrates. In another embodiment, the first and second insulating substrates may also be dielectric layers.

As described above, in this embodiment, the two first ground elements G1 are disposed below the two signal traces St, and the two second ground elements G2 are disposed above the two signal traces St. The signal traces St are disposed between the first ground elements G1 and the second ground elements G2 in order to provide an electromagnetic isolation effect.

The embodiment just exemplifies the disclosure and is not intended to limit the scope of the disclosure. Any equivalent modification and variation according to the spirit of the disclosure is to be also included within the scope of the following claims and their equivalents.

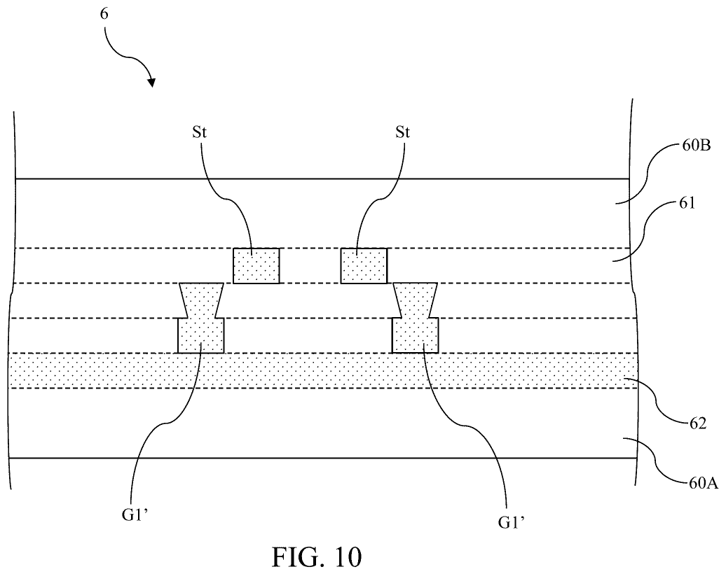

Please refer to FIG. 10, which is a cross-section view of a circuit substrate in accordance with a sixth embodiment of the disclosure. As shown in FIG. 10, the circuit substrate 6 includes an insulating substrate 60, a dielectric layer 61, a first conductor layer 62, two first ground elements G1′, and two signal traces St. The above structure is similar to the previous embodiments, so the detailed description of the above structure will not be repeated herein.

The difference between this embodiment and the fourth embodiment is that the first ground elements G1′ are ground traces.

As previously stated, in this embodiment, the two first ground elements G1′ are disposed below the two signal traces St, and the signal traces St are disposed between the first ground elements G1′ with a view to providing an electromagnetic isolation effect.

The embodiment just exemplifies the disclosure and is not intended to limit the scope of the disclosure. Any equivalent modification and variation according to the spirit of the disclosure is to be also included within the scope of the following claims and their equivalents.

Please refer to FIG. 11, which is a cross-section view of a circuit substrate in accordance with a seventh embodiment of the disclosure. As shown in FIG. 11, the circuit substrate 7 includes an insulating substrate 70, a dielectric layer 71, a first conductor layer 72, three first ground elements G1, and two signal traces St. The above structure is similar to the previous embodiments, and the detailed description of the above structure will not be repeated herein.

The first conductor layer 72 is disposed on the insulating substrate 70 and located on one side of the dielectric layer 71. In this embodiment, the first conductor layer 72 is disposed on the lower side of the dielectric layer 71.

The first ground elements G1 protrude from the first conductor layer 72 and are disposed inside the dielectric layer 71.

The signal traces St are disposed inside the dielectric layer 71 and located on one side of the first ground elements G1.

As previously stated, in this embodiment, the three first ground elements G1 are disposed below the two signal traces St. Additionally, each signal trace St is disposed between two adjacent first ground elements G1, which can form a staggered arrangement in order to provide an electromagnetic isolation effect.

The projection of each signal trace St on the first conductor layer 72 is adjacent to the projection of at least one of the first ground elements G1 on the first conductor layer 72. However, the projection of each signal trace St does not contact the projection of any one of the first ground elements G1. In this embodiment, the projections of the signal traces St and the first ground elements G1 on the first conductor layer 72 are in a staggered arrangement. The projections of the signal traces St on the first conductor layer 72 can be very close to the projection of at least one of the first ground elements G1 on the first conductor layer 72 but do not touch the projection of any one of the first ground elements G1 on the first conductor layer 72. The signal traces St also do not contact the first ground elements G1. The distance between the projection of each signal traces St and the first ground elements G1 (the shortest distance between the signal trace St and the first ground element G1) is as described in previous embodiments.

Additionally, the plane passing through the top surface of the first ground elements G1 may coincide with the plane passing through the bottom surfaces of the signal traces St. There may also be a gap between the plane passing through the top surface of the first ground elements G1 and the plane passing through the bottom surfaces of the signal traces St.

As described above, the first ground elements G1 protrude from the first conductor layer 72, and the two signal traces St are disposed above the first ground elements G1. The signal traces Sr and the first ground elements G1 are in a staggered arrangement. This structure can significantly reduce crosstalk between the signal traces St. The number and positions of the first ground elements G1 and the signal traces St can be adjusted as needed.

The embodiment just exemplifies the disclosure and is not intended to limit the scope of the disclosure. Any equivalent modification and variation according to the spirit of the disclosure is to be also included within the scope of the following claims and their equivalents.

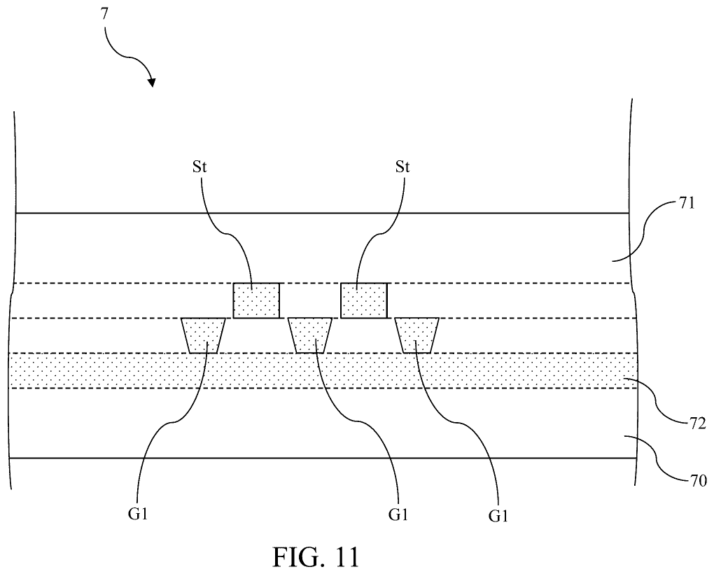

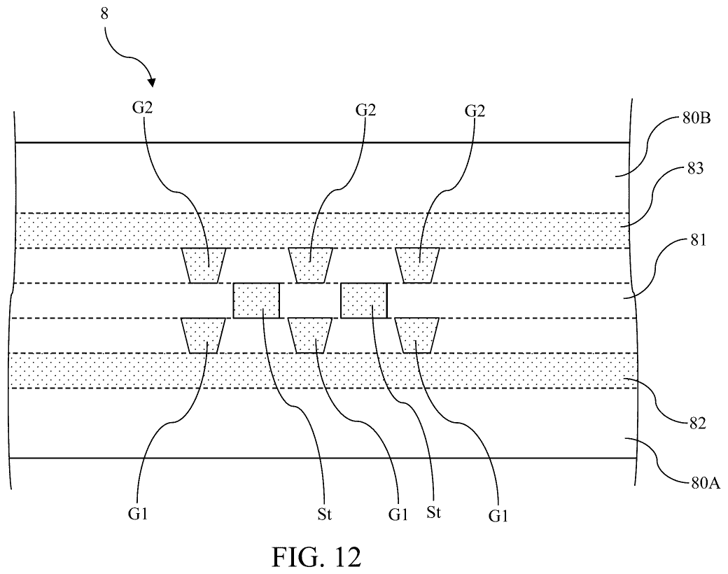

Please refer to FIG. 12, which is a cross-section view of a circuit substrate in accordance with an eighth embodiment of the disclosure. As shown in FIG. 12, the circuit substrate 8 includes a first insulating substrate 80A, a second insulating substrate 80B, a dielectric layer 81, a first conductor layer 82, a second conductor layer 83, three first ground elements G1, two signal traces St, and three second ground elements G2. The above structure is similar to the previous embodiments, so the detailed description of the above structure will not be repeated herein.

The first conductor layer 82 is disposed on the first insulating substrate 80A and located on one side of the dielectric layer 81. In this embodiment, the first conductor layer 82 is disposed on the lower side of the dielectric layer 81.

The first ground elements G1 protrude from the first conductor layer 82 and are disposed inside the dielectric layer 81.

The signal traces St are disposed inside the dielectric layer 81 and located on one side of the first ground elements G1.

The difference between this embodiment and the seventh embodiment is that this embodiment further includes three second ground elements G2 and a second conductor layer 83 disposed above the signal traces St. The second ground elements G2 are disposed above the signal traces St. and the second ground elements G2 and the signal traces St are in a staggered arrangement. The second ground elements G2 symmetrically aligned with the first ground elements G1. The second conductor layer 83 is disposed on the upper side of the dielectric layer 81, and the second ground elements G2 protrude from the second conductor layer 83. The second insulating substrate 80B is disposed on the second conductor layer 83. In this embodiment, both the first insulating substrate 80A and the second insulating substrate 80B are glass substrates. In another embodiment, the insulating substrates may also be dielectric layers.

As set forth above, in this embodiment, the three first ground elements G1 are disposed below the two signal traces St. Additionally, each signal trace St is disposed between two adjacent first ground elements G1 to achieve a staggered arrangement, which can provide an electromagnetic isolation effect. Similarly, the three second ground elements G2 are disposed above the two signal traces St. Each signal trace St is disposed between two adjacent second ground elements G2 to achieve a staggered arrangement, which can enhance the electromagnetic isolation effect.

The embodiment just exemplifies the disclosure and is not intended to limit the scope of the disclosure. Any equivalent modification and variation according to the spirit of the disclosure is to be also included within the scope of the following claims and their equivalents.

Please refer to FIG. 13, which is a cross-section view of a circuit substrate in accordance with a ninth embodiment of the disclosure. As shown in FIG. 13, the circuit substrate 9 includes a first insulating substrate 90A, a second insulating substrate 90B, a dielectric layer 91, a first conductor layer 92, three first ground elements G1, and two signal traces St. This above structure is similar to the previous embodiments, so the detailed description of the above structure will not be repeated herein.

The first conductor layer 92 is disposed on one side of the dielectric layer 91. In this embodiment, the first conductor layer 92 is disposed on the upper side of the dielectric layer 91, and the dielectric layer 91 is disposed on the first insulating substrate 90A.

The first ground elements G1 protrude from the first conductor layer 92 and are disposed inside the dielectric layer 91.

The signal traces St are disposed inside the dielectric layer 91 and located on one side of the first ground elements G1. The second insulating substrate 90B is disposed on the first conductor layer 92. In this embodiment, both the first insulating substrate 90A and the second insulating substrate 90B are glass substrates. In another embodiment, these insulating substrates may also be dielectric layers.

As described above, in this embodiment, the three first ground elements G1 are disposed above the two signal traces St. Additionally, each signal trace St is disposed between two adjacent first ground elements G1 to achieve a staggered arrangement, which can provide an electromagnetic isolation effect.

The projection of each signal trace St on the first conductor layer 92 is adjacent to the projection of at least one of the first ground elements G1 on the first conductor layer 92. However, the projection of each signal trace St does not contact the projection of any one of the first ground elements G1. In this embodiment, the projections of the signal traces St and the first ground elements G1 onto the first conductor layer 92 are staggered. The projections of the signal traces St can be very close to at least one projection of the first ground elements G1 but do not touch them. The signal traces St also do not contact the first ground elements G1. The distance between the projection of each signal trace St and the first ground elements G1 (the shortest distance between the signal trace St and the first ground element G1) is as described in previous embodiments.

Furthermore, the plane passing through the bottom surfaces of the first ground elements G1 may coincide with the plane passing through the top surfaces of the signal traces St. There may also be a gap between the plane passing through the bottom surfaces of the first ground elements G1 and the plane passing through the top surfaces of the signal traces St.

As described above, the first ground elements G1 protrude from the first conductor layer 92, and the two signal traces St are disposed below the first ground elements G1. The signal traces St and the first ground elements G1 are in a staggered arrangement. This structure can significantly reduce crosstalk between the signal traces St. The number and positions of the first ground elements G1 and the signal traces St can be adjusted as needed.

The embodiment just exemplifies the disclosure and is not intended to limit the scope of the disclosure. Any equivalent modification and variation according to the spirit of the disclosure is to be also included within the scope of the following claims and their equivalents.

The above embodiments detail the structural design of the protruding ground barrier. Taking the first embodiment as an example, the circuit substrate 1 includes the first grounding element G1, which protrudes from the first conductor layer 12 of the circuit substrate 1 and is disposed inside the dielectric layer 11 of the circuit substrate 1. The signal traces St of the circuit substrate 1 are disposed inside the dielectric layer 11 and located on one side of the first ground element G1. The projection of each signal trace St on the first conductor layer 12 is adjacent to the projection of the first grounding element G1 on the first conductor layer 12, but the projection of each signal trace St on the first conductor layer 12 does not contact the projection of the first grounding element G1 on the first conductor layer 12. The first ground element G1 protrudes from the first conductor layer 12 to form a protruding ground barrier, which can effectively isolate electromagnetic fields and reduce crosstalk between signal traces St. As a result, the circuit substrate 1 effectively addresses the issue of crosstalk arising during high-speed signal transmission and high-frequency operation, so the circuit substrate can meet the requirements of various applications.

Moreover, each signal trace St of the circuit substrate 1 is extremely close to at least one first ground element G1 but does not contact the first grounding element G1. Consequently, the first ground element G1 not only serves as a protruding ground barrier to effectively isolate electromagnetic fields and reduce crosstalk between signal traces St, but also avoids conductive anodic filament (CAF) and leakage currents. Thus, the reliability of the circuit substrate 1 can be enhanced, such that the circuit substrate can conform to actual requirements.

Furthermore, the structural design of the circuit substrate 1 provides a scalable structure that can be integrated with currently available manufacturing processes and applied to various heterogeneous packaging structures, such as 2.XD IC packaging, 3D IC packaging, SiP (System in Package), PoP (Package on Package), and Fanout packaging. Therefore, the circuit substrate 1 can achieve significant area reduction while supporting high signal transmission density. As a result, the computational performance and processing time of the circuit substrate 1 can be greatly improved, so the circuit substrate 1 can satisfy the demands of high-performance computing (HPC) and artificial intelligence (AI) fields. Therefore, the circuit substrate 1 aligns with the trends of future development.

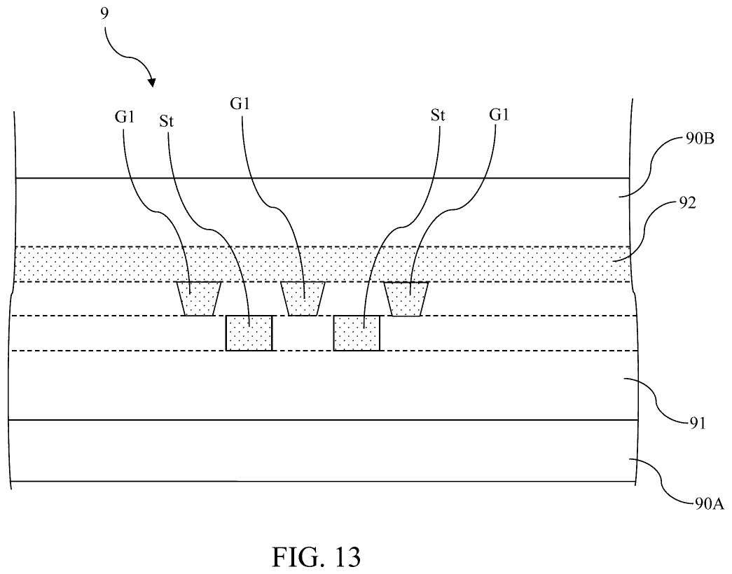

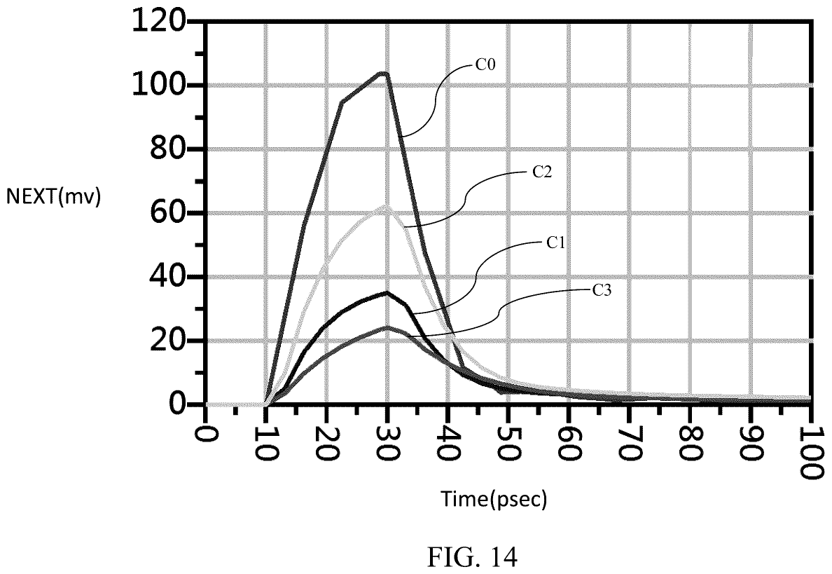

Please refer to FIG. 14, which is a first curve chart of an electromagnetic simulation of the circuit substrates of the embodiments of the disclosure. FIG. 14 shows the electromagnetic simulation result for near-end crosstalk (NEXT). As shown in FIG. 14, the curve C0 stands for the electromagnetic simulation results for a circuit substrate without a protruding ground barrier (with the first ground element G1 of the first embodiment removed). The curve C1 stands for the electromagnetic simulation result for the circuit substrate 1 of the first embodiment. The curve C2 stands for the electromagnetic simulation result for the circuit substrate 4 of the fourth embodiment. The curve C3 stands for the electromagnetic simulation result for the circuit substrate 7 of the seventh embodiment. FIG. 14 shows that the circuit substrates 1, 4, and 7 effectively reduce near-end crosstalk, outperforming the circuit substrate without the protruding ground barrier. The circuit substrate 1 exhibits the best performance in reducing near-end crosstalk.

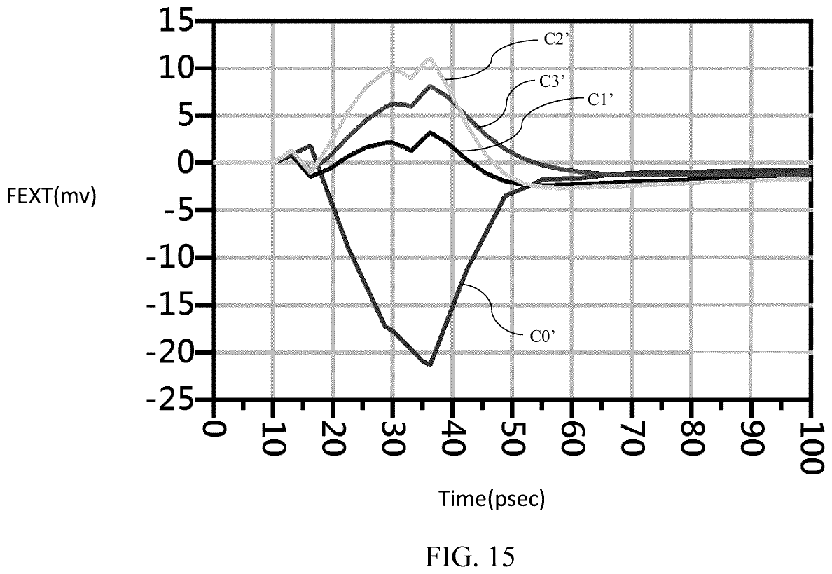

Please refer to FIG. 15, which is a second curve chart of the electromagnetic simulation of the circuit substrates of the embodiments of the disclosure. FIG. 15 shows the electromagnetic simulation result for far-end crosstalk (FEXT). As shown in FIG. 15, the curve C0′ stands for the electromagnetic simulation result for a circuit substrate without a protruding ground barrier (with the first ground element G1 of the first embodiment removed). The curve C1′ stands for the electromagnetic simulation result for the circuit substrate 1 of the first embodiment. The curve C2′ stands for the electromagnetic simulation result for the circuit substrate 4 of the fourth embodiment. The curve C3′ stands for the electromagnetic simulation result for the circuit substrate 7 of the seventh embodiment. As observed, the circuit substrates 1, 4, and 7 effectively reduce far-end crosstalk, outperforming the circuit substrate without the protruding ground barrier. The circuit substrate 1 also demonstrates the best performance in reducing far-end crosstalk.

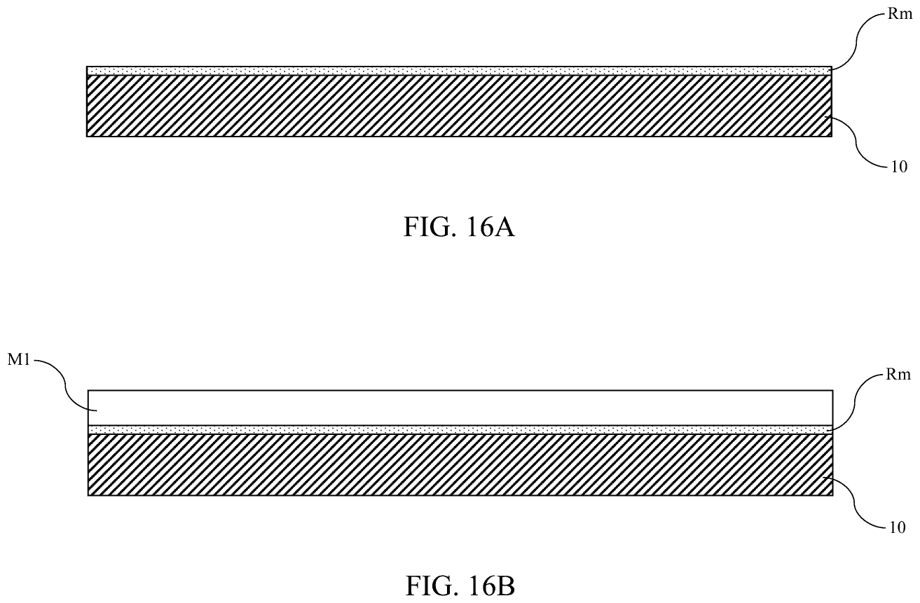

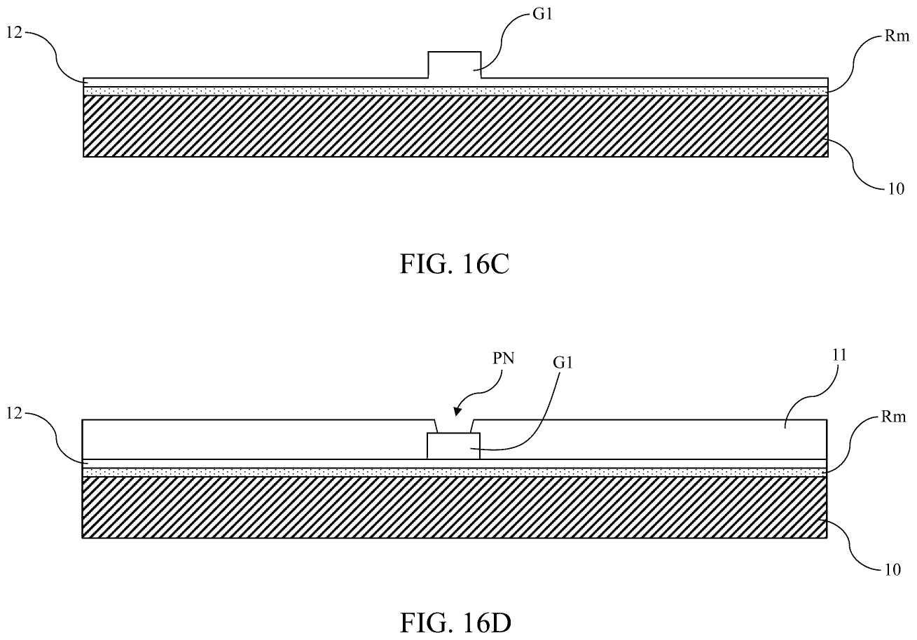

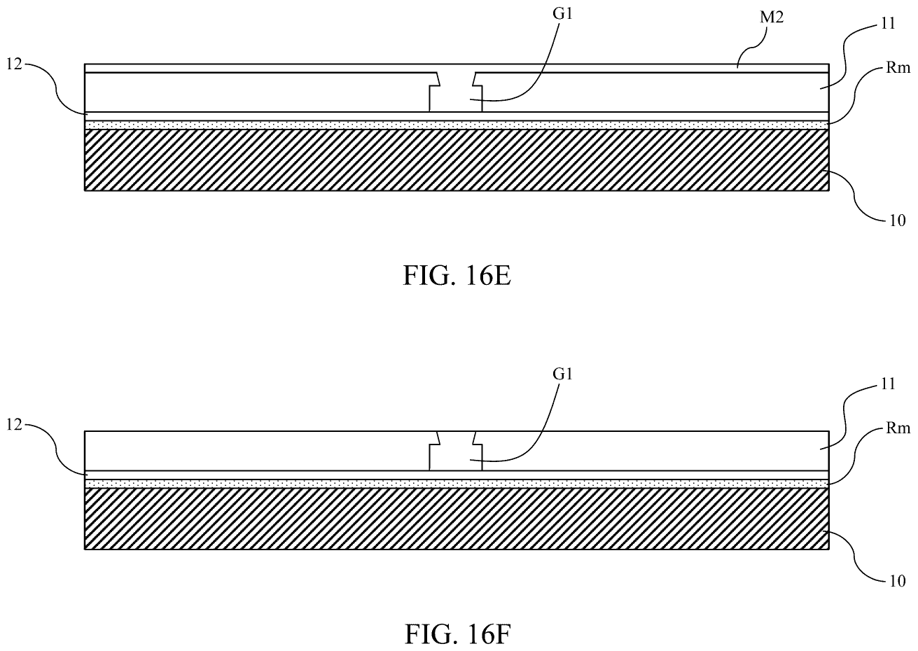

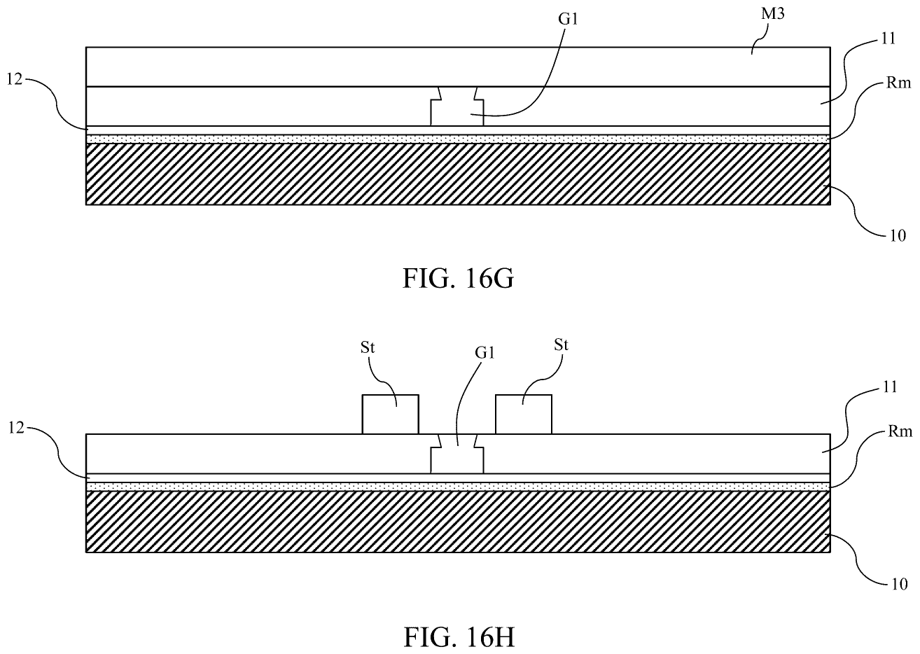

Please refer to FIG. 16A to FIG. 16H, which are first to eighth schematic views of a method for manufacturing a circuit substrate in accordance with a tenth embodiment of the disclosure. This embodiment takes the circuit substrate 1 of the first embodiment as an example to describe the manufacturing method thereof. As shown in FIG. 16A, the first step is to provide an insulating substrate 10 (e.g., a glass substrate), and then a release film coating process is performed to form a release film Rm on the insulating substrate 10.

As shown in FIG. 16B, a first metal layer coating process is then performed to form the first metal layer M1. The first metal layer coating process includes two steps. The first step is to form a first seed layer on the insulating substrate 10. The second step is to perform a first metal plating process on the first seed layer to form the first metal layer M1.

Next, as shown in FIG. 16C, a first lithography process is performed on the first metal layer M1 to form the first ground element G1 and the first conductor layer 12, and then a photoresist stripping process is executed.

As shown in FIG. 16D, a dielectric layer formation process is performed to form a dielectric layer 11 covering the first conductor layer 12 and the first ground element G1. An opening process is then performed to form an opening PN in the dielectric layer 11 so as to expose the first ground element G1 through the opening PN.

As shown in FIG. 16E, a second metal layer coating process is performed to form a second conductor layer M2 on the dielectric layer 11. The second metal layer coating process includes two steps. The first step is to form a second seed layer on the dielectric layer 11. The second step is to perform a second metal plating process on the second seed layer to form the second metal layer M2, and then a photoresist stripping process is performed.

Next, as shown in FIG. 16F, a grinding process is performed to remove the portions of the second metal layer M2 outside the opening PN of the dielectric layer 11. Consequently, one side of the first ground element G1 does not contact any metal layer.

As shown in FIG. 16G, a third metal layer coating process is performed to form a third metal layer M3 on the dielectric layer 11. The third metal layer coating process includes two steps. The first step is to form a third seed layer on the dielectric layer 11. The second step is to perform a third metal plating process on the third seed layer to form the third metal layer M3.

Subsequently, as shown in FIG. 16H, a second lithography process is performed on the third metal layer M3 to form two signal traces St, and then a photoresist stripping process is executed.

By selectively executing the above steps, the structure of any of the embodiments described above can be achieved.

The embodiment just exemplifies the disclosure and is not intended to limit the scope of the disclosure. Any equivalent modification and variation according to the spirit of the disclosure is to be also included within the scope of the following claims and their equivalents.

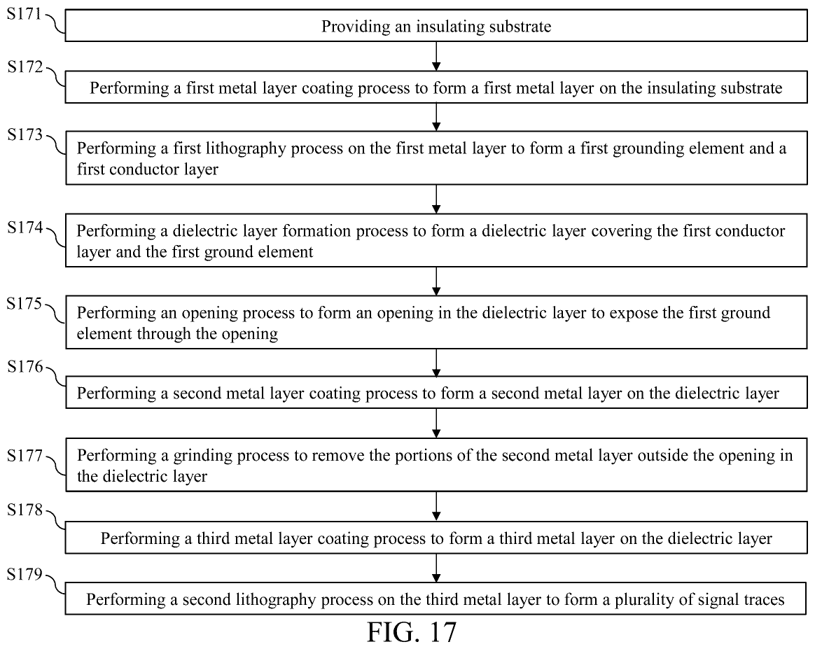

Please refer to FIG. 17, which is a flow chart of a method for manufacturing a circuit substrate in accordance with an eleventh embodiment of the disclosure. As shown in FIG. 17, the method for manufacturing the circuit substrate of this embodiment includes the following steps:
Step S171: providing an insulating substrate.
Step S172: performing a first metal layer coating process to form a first metal layer on the insulating substrate.
Step S173: performing a first lithography process on the first metal layer to form a first grounding element and a first conductor layer.
Step S174: performing a dielectric layer formation process to form a dielectric layer covering the first conductor layer and the first ground element.
Step S175: performing an opening process to form an opening in the dielectric layer to expose the first ground element through the opening.
Step S176: performing a second metal layer coating process to form a second metal layer on the dielectric layer.
Step S177: performing a grinding process to remove the portions of the second metal layer outside the opening in the dielectric layer.
Step S178: performing a third metal layer coating process to form a third metal layer on the dielectric layer.
Step S179: performing a second lithography process on the third metal layer to form a plurality of signal traces.

The structure of the circuit substrate manufactured by the above method is similar to those of the previous embodiments, so will not be described herein.

The embodiment just exemplifies the disclosure and is not intended to limit the scope of the disclosure. Any equivalent modification and variation according to the spirit of the disclosure is to be also included within the scope of the following claims and their equivalents.

Although the operations of the method(s) herein are shown and described in a particular order, the order of the operations of each method may be altered so that certain operations may be performed in an inverse order or so that certain operations may be performed, at least in part, concurrently with other operations. In another embodiment, instructions or sub-operations of distinct operations may be implemented in an intermittent and/or alternating manner.

To sum up, according to the embodiments of the disclosure, the circuit substrate includes the first grounding element, which protrudes from the first conductor layer of the circuit substrate and is disposed inside the dielectric layer of the circuit substrate. The signal traces of the circuit substrate are disposed inside the dielectric layer and located on one side of the first ground element. The projections of each signal line on the first conductor layer is adjacent to the projection of the first grounding element on the first conductor layer, but the projection of each signal line on the first conductor layer does not contact the projection of the first grounding element on the first conductor layer. The first ground element protrudes from the first conductor layer to form a protruding ground barrier, which can effectively isolate electromagnetic fields and reduce crosstalk between signal traces. As a result, the circuit substrate effectively addresses the issue of crosstalk arising during high-speed signal transmission and high-frequency operation, so the circuit substrate can meet the requirements of various applications.

Further, according to the embodiments of the disclosure, each signal line of the circuit substrate is extremely close to at least one first ground element but does not contact the first grounding element. Consequently, the first ground element not only serves as a protruding ground barrier to effectively isolate electromagnetic fields and reduce crosstalk between signal traces, but also avoids conductive anodic filament (CAF) and leakage currents. Thus, the reliability of the circuit substrate can be enhanced, such that the circuit substrate can conform to actual requirements.

Moreover, according to the embodiments of the disclosure, the structural design of the circuit substrate provides a scalable structure that can be integrated with currently available manufacturing processes and applied to various heterogeneous packaging structures. Therefore, the circuit substrate can achieve significant area reduction while supporting high signal transmission density. As a result, the computational performance and processing time of the circuit substrate can be greatly improved, so the circuit substrate can satisfy the demands of high-performance computing (HPC) and artificial intelligence (Al) fields. Therefore, the circuit substrate aligns with the trends of future development.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A circuit substrate, comprising:
a dielectric layer;
a first conductor layer disposed on one side of the dielectric layer;
a first ground element protruding from the first conductor layer and disposed inside the dielectric layer; and
a plurality of signal traces disposed inside the dielectric layer and located on one side of the first ground element;
wherein a projection of each of the signal traces on the first conductor layer is adjacent to a projection of the first ground element on the first conductor layer, while the projection of each of the signal traces on the first conductor layer does not contact the projection of the first ground element on the first conductor layer.

2. The circuit substrate as claimed in claim 1, wherein the first ground element is one or more via.

3. The circuit substrate as claimed in claim 1, wherein the first ground element is a ground trace.

4. The circuit substrate as claimed in claim 1, wherein the projection of the first ground element on the first conductor layer is located between the projections of the signal traces on the first conductor layer.

5. The circuit substrate as claimed in claim 1, wherein the first conductor layer is disposed on a lower side of the dielectric layer, the signal traces are disposed above the first ground element, and a plane passing through a top surface of the first ground element coincides with a plane passing through bottom surfaces of the signal traces.

6. The circuit substrate as claimed in claim 1, wherein the first conductor layer is disposed on a lower side of the dielectric layer, the signal traces are disposed above the first ground element, and there is a gap between a plane passing through a top surface of the first ground element and a plane passing through bottom surfaces of the signal traces.

7. The circuit substrate as claimed in claim 1, wherein the first conductor layer is disposed on an upper side of the dielectric layer, the signal traces are located below the first ground element, and a plane passing through a bottom surface of the first ground element coincides with a plane passing through top surfaces of the signal traces.

8. The circuit substrate as claimed in claim 1, wherein the first conductor layer is disposed on a lower side of the dielectric layer, the signal traces are located below the first ground element, and there is a gap between a plane passing through a bottom surface of the first ground element and a plane passing through top surfaces of the signal traces.

9. The circuit substrate as claimed in claim 1, further comprising a second conductor layer and a second ground element, wherein the second conductor layer is disposed on another side of the dielectric layer, the second ground element protrudes from the second conductor layer and is disposed inside the dielectric layer, and the projection of each of the signal traces on the second conductor layer is adjacent to a projection of the second ground element on the second conductor layer, but does not contact the projection of the second ground element on the second conductor layer.

10. The circuit substrate as claimed in claim 9, wherein the second ground element is a via.

11. The circuit substrate as claimed in claim 9, wherein the second ground element is a ground trace.

12. A circuit substrate, comprising:
a dielectric layer;
a first conductor layer disposed on one side of the dielectric layer;
a plurality of first ground elements protruding from the first conductor layer and disposed inside the dielectric layer; and
a plurality of signal traces disposed inside the dielectric layer and located on one side of the first ground element;
wherein a projection of each of the signal traces on the first conductor layer is adjacent to a projection of at least one of the first ground elements on the first conductor layer, but does not contact the projection of any one of the first ground elements on the first conductor layer.

13. The circuit substrate as claimed in claim 12, wherein the first ground element is a via.

14. The circuit substrate as claimed in claim 12, wherein the first ground element is a ground trace.

15. The circuit substrate as claimed in claim 12, wherein the projections of the signals traces on the first conductor layer are located between the projections of the first ground elements on the first conductor layer.

16. The circuit substrate as claimed in claim 12, wherein the projections of the signals traces on the first conductor layer and the projections of the first ground elements on the first conductor layer are in a staggered arrangement.

17. The circuit substrate as claimed in claim 12, wherein the first conductor layer is disposed on a lower side of the dielectric layer, the signal traces are disposed above the first ground elements, and a plane passing through top surfaces of the first ground elements coincides with a plane passing through bottom surfaces of the signal traces.

18. The circuit substrate as claimed in claim 12, wherein the first conductor layer is disposed on a lower side of the dielectric layer, the signal traces are disposed above the first ground elements, and there is a gap between a plane passing through top surfaces of the first ground elements and a plane passing through bottom surfaces of the signal traces.

19. The circuit substrate as claimed in claim 12, wherein the first conductor layer is disposed on an upper side of the dielectric layer, the signal traces are located below the first ground elements, and a plane passing through bottom surfaces of the first ground elements coincides with a plane passing through top surfaces of the signal traces.

20. The circuit substrate as claimed in claim 12, wherein the first conductor layer is disposed on an upper side of the dielectric layer, the signal traces are located below the first ground element, and there is a gap between a plane passing through bottom surfaces of the first ground elements and a plane passing through top surfaces of the signal traces.

21. The circuit substrate as claimed in claim 12, further comprising a second conductor layer and a plurality of second ground elements, wherein the second conductor layer is disposed on another side of the dielectric layer, the second ground elements protrude from the second conductor layer and are disposed inside the dielectric layer, and the projection of each of the signal traces on the second conductor layer is adjacent to a projection of at least one of the second ground elements on the second conductor layer, but does not contact the projection of any one of the second ground elements on the second conductor layer.

22. The circuit substrate as claimed in claim 21, wherein the second ground element is a via.

23. The circuit substrate as claimed in claim 21, wherein the second ground element is a ground trace.

24. A method for manufacturing a circuit substrate, comprising:
providing an insulating substrate;
performing a first metal layer coating process to form a first metal layer on the insulating substrate;
performing a first lithography process on the first metal layer to form a first grounding element and a first conductor layer;
performing a dielectric layer formation process to form a dielectric layer covering the first conductor layer and the first ground element;
performing an opening process to form an opening in the dielectric layer to expose the first ground element through the opening;
performing a second metal layer coating process to form a second metal layer on the dielectric layer;
performing a grinding process to remove portions of the second metal layer outside the opening in the dielectric layer;
performing a third metal layer coating process to form a third metal layer on the dielectric layer; and
performing a second lithography process on the third metal layer to form a plurality of signal traces.

25. The method for manufacturing the circuit substrate as claimed in claim 24, further comprising:
performing a release film coating process to form a release film on the insulating substrate.

26. The method for manufacturing the circuit substrate as claimed in claim 24, wherein a step of performing the first metal layer coating process to form the first metal layer on the insulating substrate comprises:
forming a first seed layer on the insulating substrate; and
performing a first metal plating process to form the first metal layer on the first seed layer.

27. The method for manufacturing the circuit substrate as claimed in claim 24, wherein a step of performing the second metal layer coating process to form the second metal layer on the dielectric layer comprises:
forming a second seed layer on the dielectric layer; and
performing a second metal plating process to form the second metal layer on the second seed layer.

28. The method for manufacturing the circuit substrate as claimed in claim 24, wherein a step of performing the third metal layer coating process to form the third metal layer on the dielectric layer comprises:
forming a third seed layer on the dielectric layer; and
performing a third metal plating process to form the third metal layer on the third seed layer.

29. The method for manufacturing the circuit substrate as claimed in claim 24, wherein the insulating substrate is a glass substrate.
